(19) United States
(12) Patent Application Publication
(10) Pub. No.: US 2014/0210450 A1
(43) Pub. Date: Jul. 31, 2014

(54) METHODS AND APPARATUS FOR ESTIMATING RETURN LOSS

(71) Applicant: NOKIA SIEMENS NETWORKS OY, Espoo (FI)

(72) Inventors: Darrell Barabash, Grapevine, TX (US); Russell Morris, Keler, TX (US); Donald Hutton, Argyle, TX (US)

(73) Assignee: Nokia Siemens Networks Oy, Espoo (FI)

(21) Appl. No.: 13/749,998

(22) Filed: Jan. 25, 2013

(51) Int. Cl. G01R 21/00

(52) U.S. Cl. CPC G01R 21/006
USPC 324/76.38

(57) ABSTRACT

Systems and techniques for return loss estimation are described. A forward power sample is taken from a power amplifier of a transmitter by sampling a feedback signal used for power control of the amplifier, and a reflected power sample at an output of the power amplifier is taken by observing the power at a circulator termination of the power amplifier. A difference determination is made for the forward power sample and the fleeted power sample in the analog domain to determine a return loss and may be digitized for further processing such as return loss measurement and comparison against thresholds. A further comparator circuit may be used to insure that measurements are made when the signal strength is adequate.

### TECHNICAL FIELD

The present invention relates generally to telecommunications. More particularly, the invention relates to systems and techniques for estimating a return loss experienced by a transmitter.

### BACKGROUND

As the number of wireless communications users continues to increase and as their demands for services increase, operators increasingly seek to provide uninterrupted service while managing the cost of infrastructure. Redundancy is costly, and a less expensive solution is to detect anomalies and degradations of service before they manifest themselves as failures or become so severe as to impair the experience of users. One vital part of the service provided to users is the signal power delivered to users by network transmitters, and one way to detect degradation of service is to detect decreases in transmit power.

One convenient measure relating to transmit power degradation is voltage standing wave ratio (VSWR) or (equivalently) return loss. Return loss indicates the condition of a transmitter antenna and its cable and connector system, and return loss can be monitored in real time. Changes in return loss indicate changes (usually faults or deterioration) in the antenna and connectors, and monitoring return loss allows early detection of and response to faults or deterioration affecting the antenna and connectors. Return loss is the ratio of incident and reflected powers, expressed in dB. Traditionally, analog signals have been processed (detected) to determine their power, and digitized, and their ratio has been computed and converted to dB using digital techniques. Various difficulties attend the determination of return loss through direct measurement of signals. Equipment for detecting and measuring signals requires some means to separate the incident and reflected signal, such as a directional coupler or bridge. This and other equipment occupies space. Processing may require sampling rates for some signals that are be difficult to achieve, and computation of the needed ratio may consume substantial processing resources.

### SUMMARY

In one embodiment of the invention, a method comprises taking a forward power sample of a power amplifier of a transmitter by sampling a feedback signal used for power control of the amplifier, taking a reflected power sample of the power amplifier and estimating return loss of the transmitter based on the sampling of the feedback signal and the reflected power. Estimating return loss comprises estimating return loss at the input of a transmit filter used by the transmitter and comprises estimating return loss in an analog domain.

In another embodiment of the invention, an apparatus comprises a first detector configured to take a forward power sample of the power amplifier of a transmitter by sampling a feedback signal used for power control of the amplifier, at leas one of a circulator and an isolator at an output of the power amplifier, and a second detector configured to take a reflected power sample of the power amplifier through the at least one of the isolator and the circulator. The apparatus further comprises a comparison module configured to compare the forward power sample and the reflected power sample to produce a comparison signal providing a return loss estimate, an analog to digital converter configured to digitize the comparison signal, and a processing module configured to process the digitized comparison signal to produce a return loss measurement based on the digitized comparison signal.

### BRIEF DESCRIPTION OF HIE DRAWINGS

FIG. 1 illustrates elements for estimating return loss according to an embodiment of the present invention:

FIGS. 2 and 3 illustrate processes according to embodiments of the present invention;

FIG. 4 illustrates a diagram showing signal relationships according to an embodiment of the present invention;

FIGS. 5-7 illustrate graphs of various aspects of return loss measurements according to embodiments of the present invention;

FIG. 8 illustrates return loss estimates and measurements for differing confidence bounds.

FIG. 9 illustrates return loss error for differing confidence bounds.

FIG. 10 illustrates graphs of measurement error using parameters from a prototype filter according to an embodiment of the present invention;

FIG. 11 illustrates graphs of measurement error using a prototype filter and a cable of a specified length;

FIGS. 12 and 13 illustrate graphs of multi-carrier measurement errors for differing confidence levels according to an embodiment of the present invention; and

FIGS. 14 and 15 illustrate false alarm probabilities for return loss estimation according to an embodiment of the present invention.

### DETAILED DESCRIPTION

Embodiments of the present invention recognize that digital computation the ratio of analog signals generally requires two analog to digital converters (ADCs) or a multiplexed ADC. Furthermore, digitization of the envelope of the signals requires sampling faster than the Nyquist rate. Particularly in the case of multi-carrier signals, achieving such a sampling rate may be difficult because the instantaneous bandwidth determines the frequency content of the envelope and therefore the digitization rate. Identical undersampling would preserve the ratio but would not allow for correct power determination, often needed to bound the measurement range. An analog level detector could be used, but the measurements taken by such a detector would suffer from a large amount of modulation noise which would have to be accommodated within the dynamic range, and only filtered after digital conversion.

Embodiments of the invention further recognize that the use of dedicated log detectors produces an output proportional to dBs. In such a case, return loss becomes a simple difference calculation, easily performed in the analog domain with, for example, a differential amplifier. These log detectors are wideband and much of the modulation envelope can be removed with a simple R-C smoothing filter. These types of detectors are also inexpensive so that dedicated detectors can be used for both the incident and the reflected signals. This has the added advantages that any residual envelope will be of the same (post detection) amplitude and phase from both detectors, regardless of their mean power level. The differential amplifier can therefore completely eliminate the residual envelope in the ideal case.

Each circuit can also be implemented identically, largely negating frequency and temperature effects, because these will be the same for each circuit and will not affect the differences between the results produced by the circuits. If modulation noise is not a problem, an analog to digital converter can employ a lower sampling rate. And, it is easy to add a threshold detector to enable measurements only when the power is adequate.

In the case of TDMA signals, sharing a detector or ADC can cause difficulties. It is possible to sample, for example, the forward signal near the end of a burst, but by the time a detector or ADC is switched, a sample may be taken during blanking or even during the next time slot, during which transmission may occur at a different power. Either case will give an erroneous measurement and is recognized by one or more embodiments of the invention as another reason to use dual detectors with a real-time difference calculation.

Embodiments of the invention therefore address the use of dedicated low cost log detectors to directly determine return loss with minimal dependency on modulation characteristic, spectral content or temperature. The use of such detectors eliminates the need for high speed ADCs and greatly reducing computational resources and processing load.

Direct measurement of return loss requires the incident and reflected power signals to be isolated and measured. To make reasonably accurate measurements the isolation needs to be on the order of 30 dB. In one or more embodiments, the invention accomplishes such isolation by using resources already present in the power amplifier of a transmitter—namely, the output signal sample used for power control and a signal from the circulator of the amplifier, proportional to reflected power. The signal is obtained by simply replacing a termination (for example, 50 ohms) with an attenuator—for example, a 50 ohm and (nominally) 30 dB attenuator. Such an approach imposes virtually no detriment to cost or performance on the circulator, and avoids more costly alternatives—for example, the use of two directional couplers located between the actual antenna connector and the transmit filter, each individually tuned due to the generally narrow band nature of their directivity. Eliminating such couplers removes a significant space cost (for the physical couplers) and labor cost (for tuning).

Using the power amplifier resources in this manner provides for observation of the antenna connection through a transmit path filter rather than directly. Such an approach has the benefit of elimination the need for out of band rejection filters in either of the incident or reflected signal paths. Elimination of such filters not only achieves a cost reduction but also improves performance by keeping the detector paths identical. Elimination of individual filters eliminates the risk of measurement error that might be caused by any differences between the filters, such as differences due to frequency response, part-to-part variation or temperature.

The filter and other output path elements, however, transform the antenna load to some other impedance resulting in a return loss measurement error. One exemplary set of parameters that may be usefully employed as descriptors for this transformation effect are S-parameters. The S-parameters are not completely repeatable and vary in amplitude to some degree, but in phase to a considerable degree. It can be shown that phase variation of the reflected signal results in an error vector of relatively constant amplitude and uniform phase added to the actual antenna return loss. If sufficient phase samples are taken, the average will approach the actual load return loss. In practical application, the incident signal traverses the filter once and then the reflected signal traverses it again. With filters having 8 poles or more, the total phase rotation can be 5,000 degrees or more which is a large group delay. This large group delay means that a small frequency change can lead to a large phase change, so that the filter acts as a phase scrambler. Thus, any frequency change is equivalent to a phase change which results in phase samples. By averaging the phase samples, the actual load return loss is approached as stated earlier. In fact, the worst error is for a single CW carrier and an signal that occupies more than zero frequency span (including hopping) will result in a better estimate. Multi-carrier wideband systems are now the industry norm and approaches according to one or more embodiments of the invention are particularly well adapted to multi-carrier operation, but also operate well in a single carrier environment.

As noted above, mechanisms according to one or more embodiments of the invention exploit capabilities inherent to a typical power amplifier, rather than using purpose specific directional couplers for power sensing. In particular, a feedback signal, which may be used for power control, linearization, or both, is reused for the forward power sample and the reflected power which is normally simply dissipated by the circulator termination is sampled and used.

The return loss is estimated at the input of the transmit filter rather than directly at the antenna interface. By taking advantage of the phase scrambling resulting from the large filter delay, post detection averaging reduces measurement error as the composite signal gets wider in instantaneous bandwidth. It is ideally suited to multi-carrier and multi-mode transmission schemes.

The return loss is calculated in the analog domain directly and modulation “noise” nearly completely eliminated. Digitization of the resulting analog signal is done asynchronously at low speed as it not necessary to digitize the modulation itself. With the two analog paths being identical, the circuit is highly immune to variations due to components, temperature and signal composition.

Such techniques allow for a minimal processor load. By using an application specific integrated circuit (ASIC) to count and accumulate samples and then raise an interrupt when done, the processor can service it when able and merely has to perform a simple division. Furthermore, if the number of samples is set to some power of 2, the division reduces to a simple bit shift, easily accomplished by an ASIC.

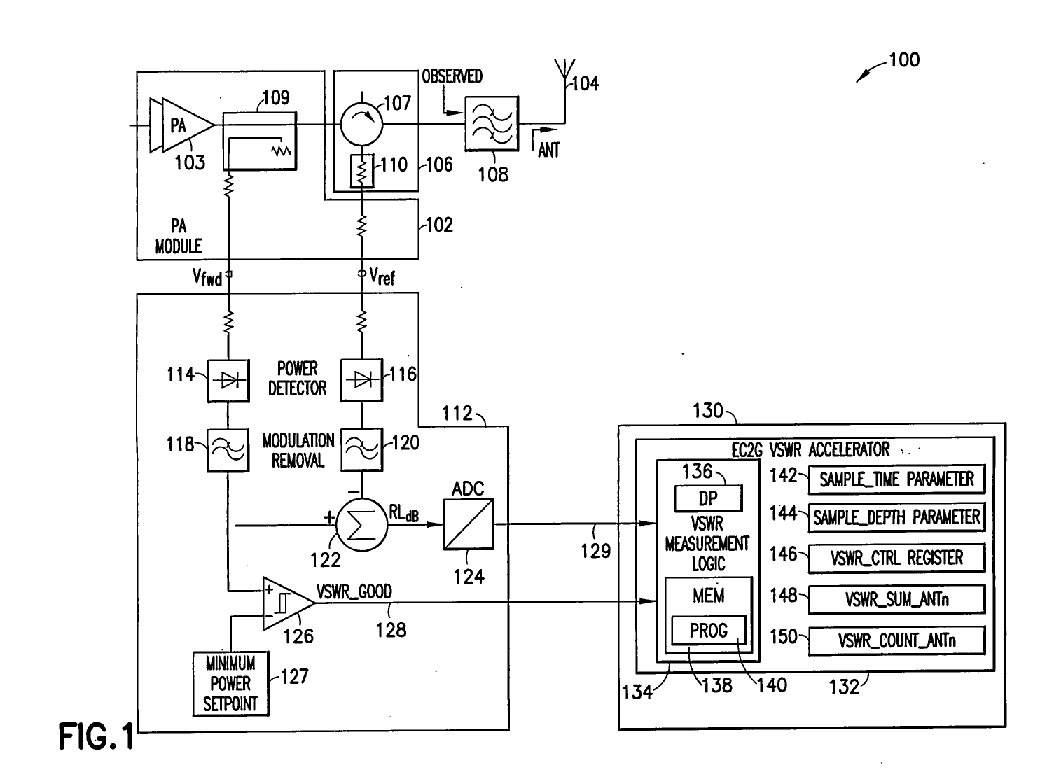

FIG. 1 illustrates a transmitter 100 according to an embodiment of the present invention. The transmitter 100 comprises a power amplifier module 102, comprising a power amplifier 103 delivering a signal to an antenna 104. A directional coupler 109 allows detection of the forward signal. It also allows for determination of adequate signal strength to ensure that the measurement is valid. An isolator/circulator 106 is interposed between the power amplifier and the antenna 104, allowing detection and analysis of the power being reflected by the antenna 104 and filter 108. It will be noted that the antenna reflection dominates when the return loss is poor.

The transmitter 100 further comprises a measurement circuit 112, allow ing measurement and digitization of relevant parameters from the power amplifier module—namely, a signal representative of the forward power and a signal from the circulator of the amplifier representative of the reflected power.

The measurement circuit 112 may comprise power detectors 114 and 116, with the power detector 114 receiving the forward power signal and the power detector 116 receiving the signal reflected power signal from the isolator 106. The measurement circuit 112 further comprises modulation removal modules 118 and 120, a differential amplifier module 122, and an analog to digital converter 124. The difference signal from the differential amplifier module 122 feeds the analog to digital converter (ADC) 124. In addition, the measurement circuit 112 comprises a comparator 126, which receives inputs from the modulation removal module 118 and a minimum power setpoint 127, and produces as an output a VSWR_Good signal 128 indicating that the signal levels are sufficient to make a valid measurement. A VSWR_Good signal 128 and an ADC output signal 129 are provided to a processing circuit 130, which in one or more embodiments may include an application specific integrated circuit. The processing circuit 130 comprises an application specific integrated circuit (ASIC)-based voltage standing wave ratio (VSWR) accelerator 131 which includes VSWR measurement logic 134. The VSWR measurement logic 134 may comprise a data processor 136, memory 138, and software including one or more programs 140. Other components of the VSWR accelerator 132 comprise storage registers 142-150 for storing, respectively, stored a sample time and sample depth parameters, a VSWR control register, and VWSR sum and VWSR count variables.

The antenna load is observed through a filter and reflected power is measured from the isolator/circulator 106 through its attenuator 110. The antenna load is observed through a filter. For narrowband signals, filtering changes across the frequency band, introducing error, but embodiments of the present invention recognize that spreading the energy in frequency is equivalent to averaging across reflection phase. Such spreading may be achieved, for example, using one or more of multiple carriers, wideband signals, frequency hopping, or other appropriate mechanisms. Long antenna lines provide a benefit in this regard if a mismatch is present at the antenna.

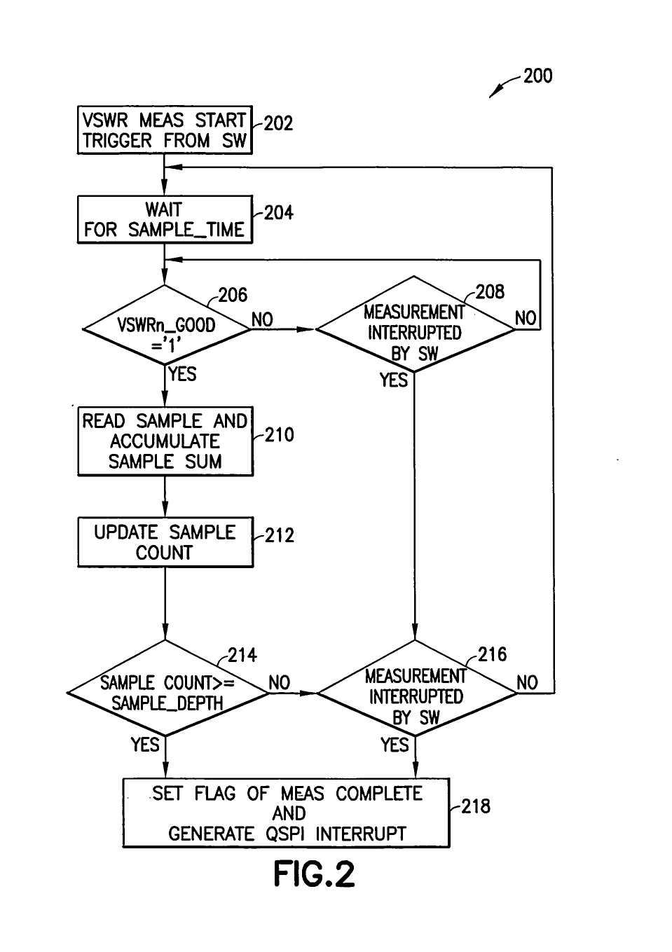

FIG. 2 illustrates a process 200 according to an embodiment of the present invention. At step 202, upon triggering event, such as a software trigger, a VSWR measurement is started. At step 204, a pause for a prescribed period, such as a specified sample time, is performed. At step 206, a determination is made if a VSWR_Good signal indicates a VSWR_Good condition. If no, the process proceeds to step 208 and a determination is made if a measurement has been interrupted by software. If no, the process returns to step 206.

If at step 208 the measurement has been interrupted by software, the process skips to step 216, and another determination is made if a measurement has been interrupted by software. If no, the process returns to step 204. If yes, the process proceeds to step 218, a measurement complete flag is set, and an interrupt is generated.

Returning now to step 206, if the VSWR_Good signal indicates a VSWR_Good condition, the process proceeds to step 210, a sample is read and a sample sum is accumulated. The process proceeds to step 212 and a sample count is updated. The process then proceeds to step 214 and a determination is made if the sample count is sufficient, suitably by comparison with a predetermined value such as SAMPLE_DEPTH. If no, the process proceeds to step 216. If yes, the process proceeds to step 218.

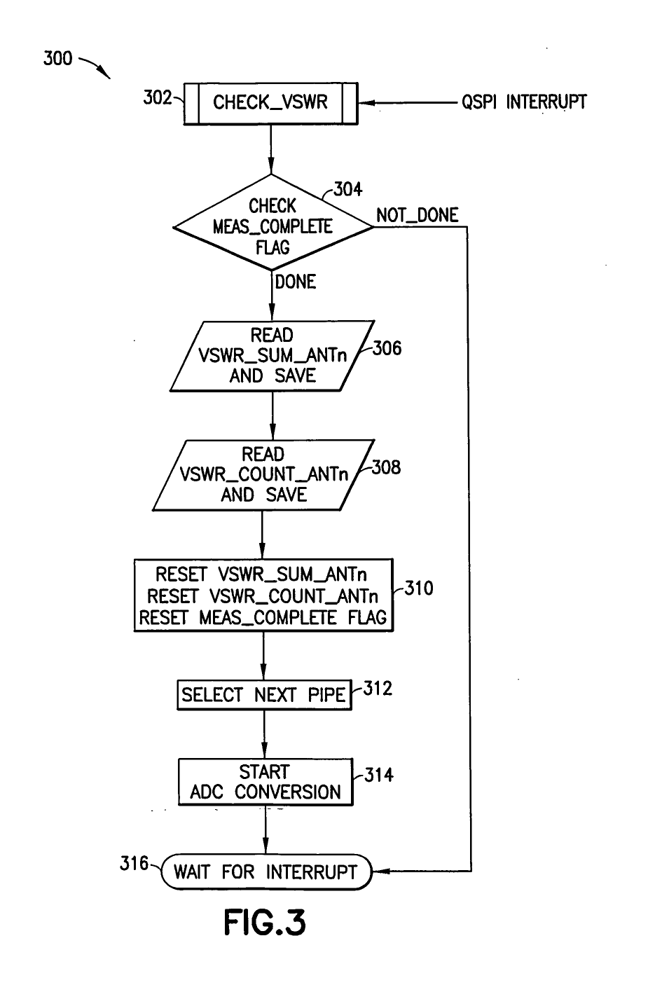

FIG. 3 illustrates a process 300 according to an embodiment of the present invention. The process 300 performs an interrupt service routine performed upon generation of an interrupt by a process such as the process 200 of FIG. 2.

At step 302, upon receiving an interrupt, a check of a VSWR value is performed. At step 304, a check is made to determine if the measurement process is complete, suitably by checking a measurement complete flag. If the measurement process is complete, the process skips to step 316, where the process terminates until another interrupt is received. If the measurement process is not complete, the process proceeds to step 306, and a sum of VWSR antenna values is read and saved. The process then proceeds to step 308, and a count of VWSR antenna measurements is read and saved. Next, at step 310, the VSWR antenna measurement sum and count values are reset and the measurement complete flag is also reset. At step 312, the next pipe is selected and at step 314, an ADC conversion is begun. The process then terminates at step 316, until another interrupt.

Various problems affecting the accuracy of the measurement are recognized and addressed by one or more embodiments of the present invention. In terms of the actual return loss measurement, the directivity of forward and reflected power samplers is a fundamental limitation. Finite directivity means that some fraction of the undesired component leaks onto the desired signal and causes seine corruption.

Returning now to FIG. 1 and referring to the VSWR measurement circuit 112, consider first the forward power sample. Any reflected power component would corrupt the forward power sample. This component, however, is lower than the desired (forward) signal by the return loss of the load being measured plus the isolation of the circulator, which is usually on the order of 26-28 dB, plus the directivity of the PDRX coupler, on the order of 20 dB. The corruption is therefore negligible.

Consider now the reflected power signal. While the undesired (forward) power signal will be reduced by the isolation of the circulator, the desired signal is reduced by the load return loss with the net effect of increased contamination at high (good) return losses. The result is an error that is larger at higher load return losses. A frequently encountered detection unit may achieve on the order of 30 dB directivity and the use of a circulator at 26-28 dB may cause some accuracy reduction.

The largest source of error is that the antenna load is observed through a filter. Complex variations in filter return loss across frequency and between different samples and vendors is impossible to compensate for. Given this, one or more embodiments of the invention use a statistical model to estimate the error for a given antenna port load.

The relationship between the observed reflection coefficient and the load reflection coefficient is:

$${Γ}_{observed} = \frac{{Γ}_{ANT} S 12 S 21}{1 - {Γ}_{ANT} S 22} + S 11 \qquad ( 1 )$$

All the parameters above are complex with the S-parameters being those of a filter being used.

Frequency being random is equivalent to phase being random and this is reflected in the statistical models. Antennas tend to be relatively low Q so that the random variable for Γ_{ANT} is modeled as constant magnitude with a uniform phase distribution. S21 and S12 are modeled in a similar manner because the phase variations are dominated by the propagation path which is many wavelengths long whereas the insertion loss is roughly constant.

For S11 and S22, while the phase tends to be uniformly distributed, the magnitude is more Rayleigh-like. This magnitude may be modeled by considering the (complex) reflection coefficient to be normally distributed in real and imaginary components. If both ports are tuned independently. S11 and S22 may be treated as independent random variables.

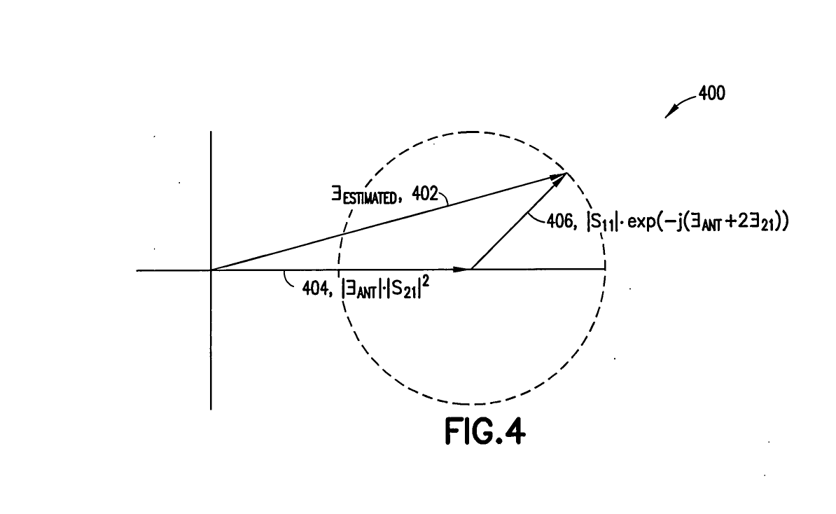

Consider practical operating conditions where the load being detected exhibits much worse return loss than the filter return loss. The equations can be simplified and the calculation illustrated with the phasor diagram 400 of FIG. 4, comprising vectors 402, 404, and 406 and noting that all the phase ambiguity has been absorbed into the the vector 406.

For a given termination at the end of some unknown length cable, the magnitude of the blue sector will be constant. Phase is influenced by a number of factors, such as filter, transmission line length, frequency, and other factors, and is not predictable, so that the vector 406 is here presumed to exhibit a uniform phase distribution. The magnitude of the vector 406 is simply the magnitude of the filter input reflection coefficient and tends to look Rayleigh like as discussed above. Given these characteristics. Γ_{ESTIMATED} is the envelope of the resultant and should exhibit a Ricean distribution:

$$f ( x \vert v , σ ) = \frac{x}{{σ}^{2}} \cdot exp ( \frac{- {x}^{2} - {v}^{2}}{2 {σ}^{2}} ) \cdot {I}_{0} ( \frac{x \cdot v}{{σ}^{2}} )$$

which would reduce to a Rayleigh distribution when ν=0. This should represent the error of a given measurement compared to its mean (true) value as measured at the transmission port of the duplex filter.

For, a circulator, the isolation is limited by the port return loss. If the port return loss is modeled in a similar way to S11 and S22 above, the same model would apply to the circulator S12.

From equation 1 above, the reflection coefficient observed looking into the filter input port is determined. Given this, it is necessary to determine what will be measured using the circulator to sample the reflected power.

Assuming a forward voltage of Vf and a reflected voltage of Vr, the measured reflection coefficient would be:

$${Γ}_{measured} = \frac{Vr + S {12}_{circulator} Vf}{Vf} \qquad ( 2 )$$

Given that:

Vr=Γ_{observed}Vf (3)

The result is that:

Γ_{measured}=Γ_{observed}+S12_{circulator} (4)

Thus, the effect of the circulator is the addition of a (complex) error to the reflection coefficient that is seen looking into the filter.

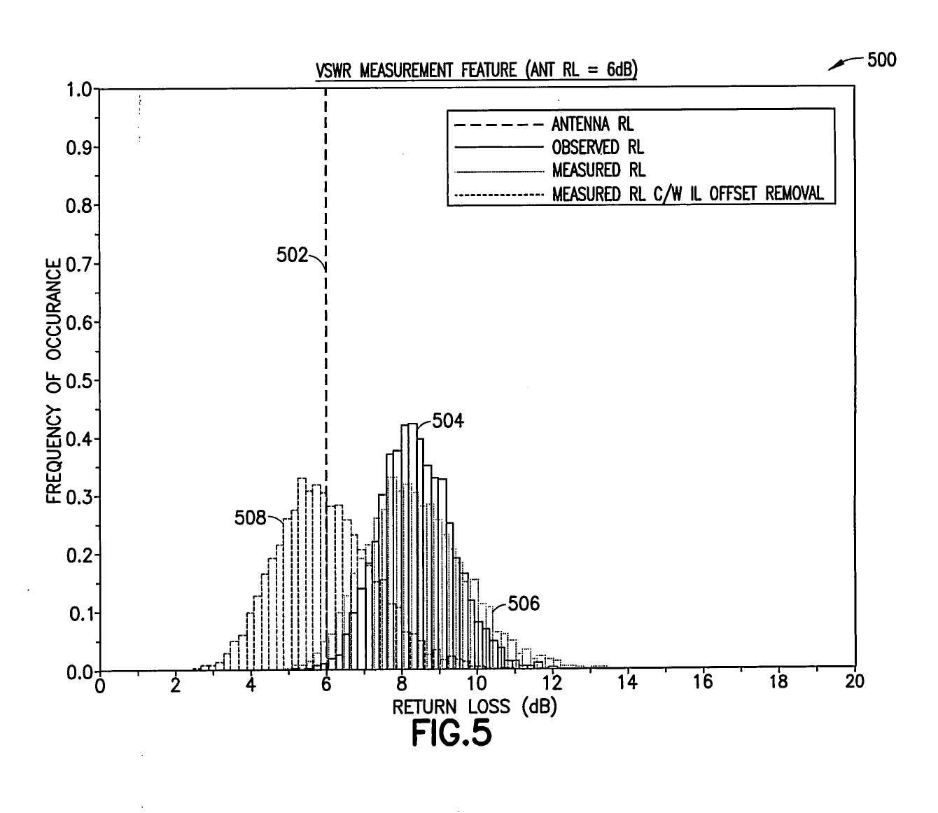

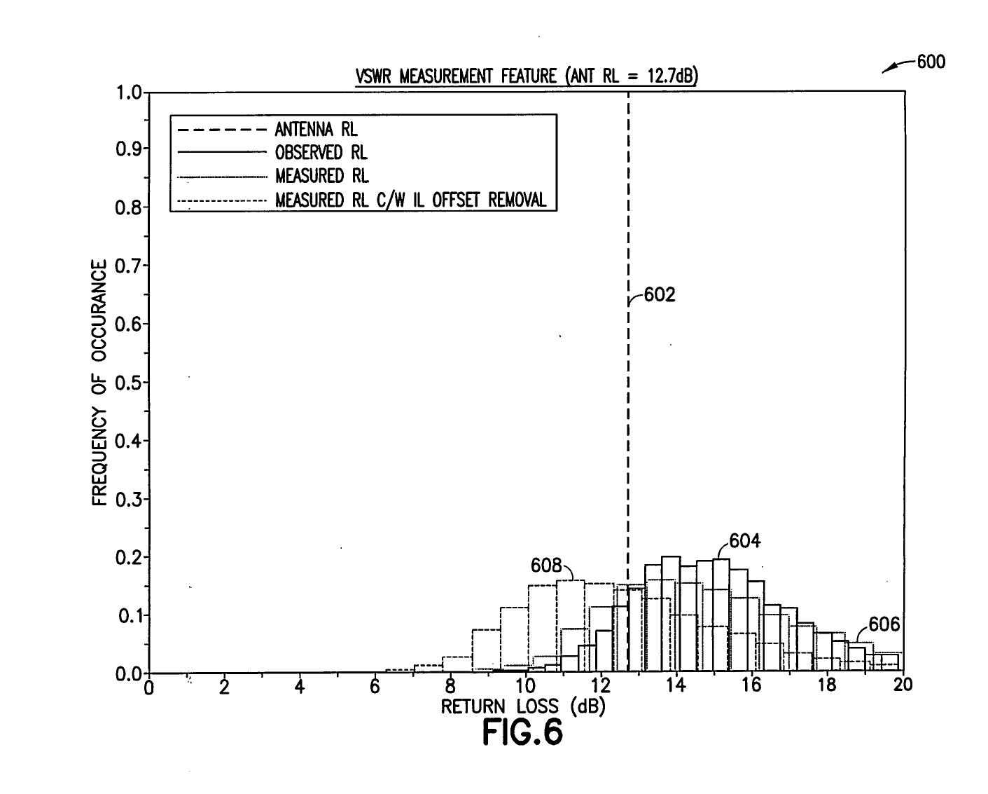

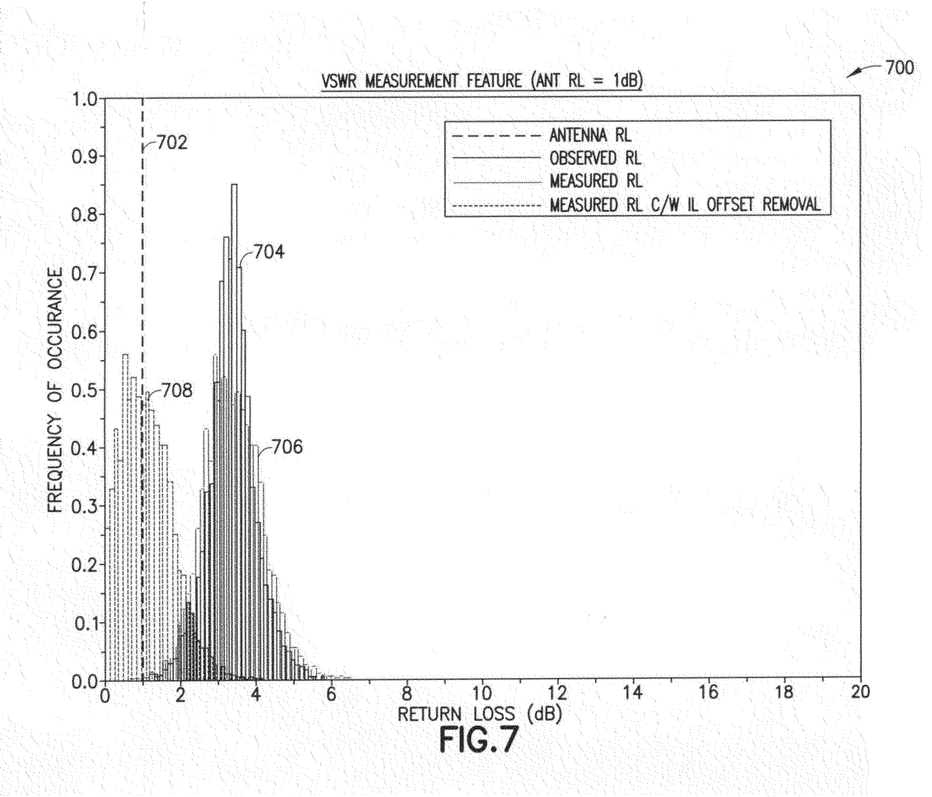

The results of suitable models of the above relationships are presented in FIGS. 5-7, illustrating graphs 500, 600, and 700, respectively, illustrating antenna loads of 6 dB return loss, 12.7 dB return loss, and 1 dB return loss. 1 dB return loss represents a completely open or shorted antenna or cable. The graph 500 illustrates curves 502-508, showing the antenna return loss, the observed return loss, the measured return loss, and the measured return loss c/w IL offset removal, respectively. The graph 600 illustrates curves 602-608, show ing the antenna return loss, the observed return loss, the measured return loss, and the measured return loss c/w IL offset removal, respectively. The graph 700 illustrates curves 702-708, showing the antenna return loss, the observed return loss, the measured return loss, and the measured return loss c/w IL offset removal, respectively.

These errors assume a single, narrow band carrier at some random carrier frequency with some random filter. The majority of the dispersion is due to the phase uncertainties of the filter in particular. As the input signal bandwidth is spread in frequency (due to modulation, multi-carriers or hopping) it is like getting samples at different phases. The sample averaging done by the algorithm becomes effectively an average over phase thus reducing the error of the estimate.

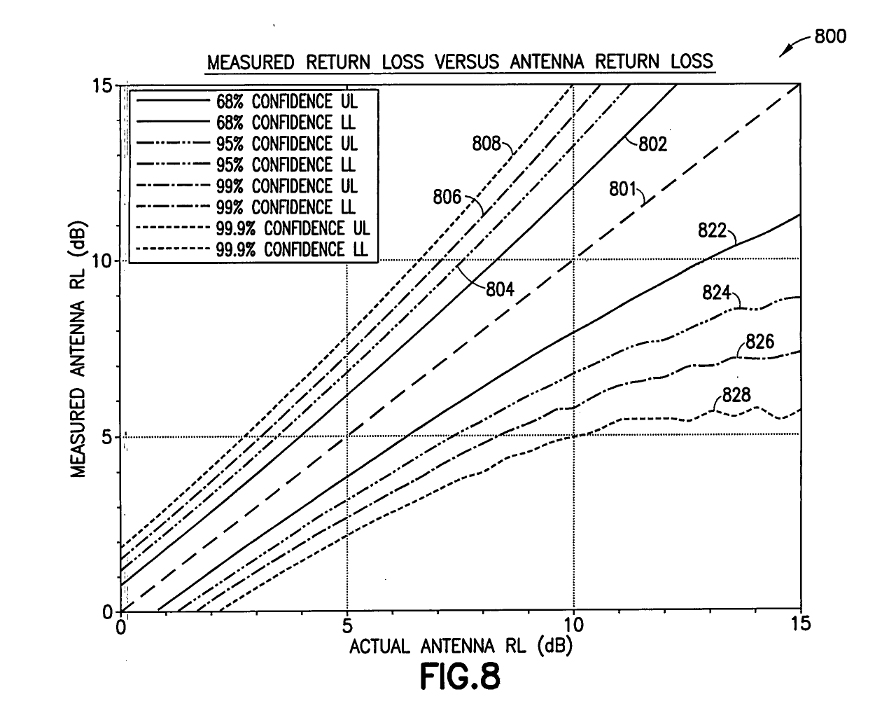

The mathematical model further allows the overall measurement error to be determined given some confidence bound. This is shown in FIG. 8, illustrating actual antenna return loss 801, and showing curves 802-808 for upper limit confidence values of 68%, 95%, 99%, and 99.9%, respectively and curves 822-828 for lower limit confidence values of 68%, 95%, 99%, and 99.9%, respectively.

FIG. 9 illustrates a graph 900 showing return loss measurement curves 902-908, having upper limit confidence values of 68%, 95%, 99%, and 99.9%, respectively.

As can be seen above, the errors grow as the antenna port return loss improves. This is because the filter variations are becoming more and more dominant. In spite of the fact that a good load cannot be accurately quantified, it is still clearly distinguishable from a very poor load. This distinction becomes more apparent as the input signal is spread over frequency which causes phase spreading and scrambling.

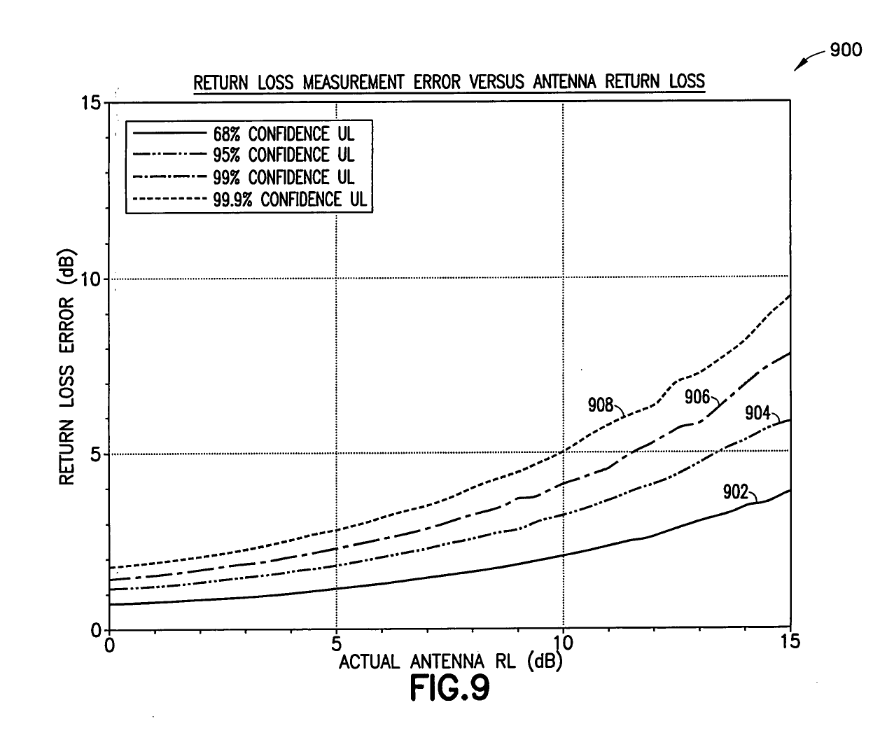

The phase effect was shown theoretically above, and can be seen in FIG. 10, which shows graph 1000 illustrating a set of curves showing measurement error and using the S-parameters from a prototype filter. Each curve is a 2 dB step starting with a 0 dB load at the end of a 3 m cable. In this the error periodicity is due to the filter impedance variation across the band. As expected, the amplitude of the error increases as the load approaches the filter S₁₁.

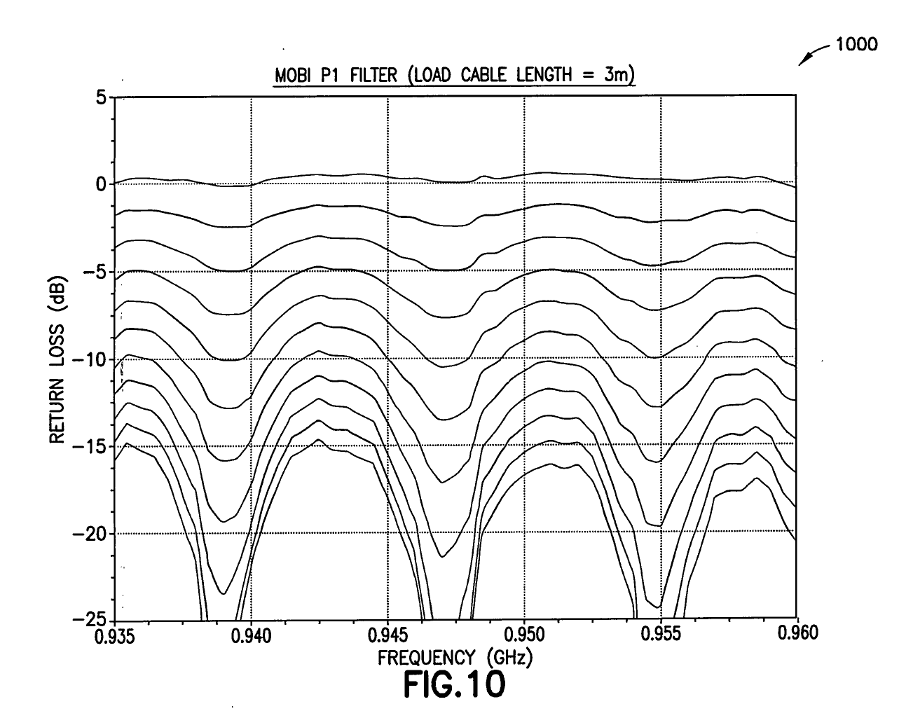

FIG. 11 shows a graph 1100 illustrating a set of curves showing measurement error using a prototype filter and a 150 m cable. As can been seen, increasing the length of cable between the load and the filter causes more rapid phase changes with frequency and helps to scramble the phases more. By taking samples across frequency, the averaging improves the estimation.

To take advantage of the averaging effect, the frequencies should be far enough apart to ensure statistically independent phases. A filter will typically have roughly (NbrPoles−1) nulls in the frequency characteristic and if the carrier spacing is large enough that they each fall between different sets of nulls, reasonable scrambling of the reflection/transmission phases will occur. If M such carriers are used, M different phase errors will be post averaged so that the standard deviation will be reduced by a factor of \sqrt{M}.

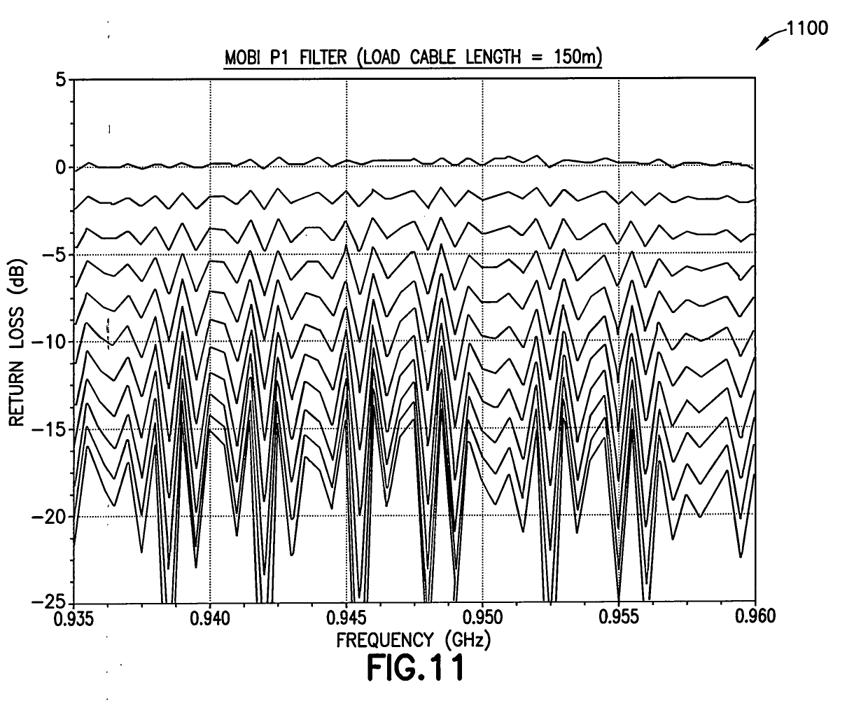

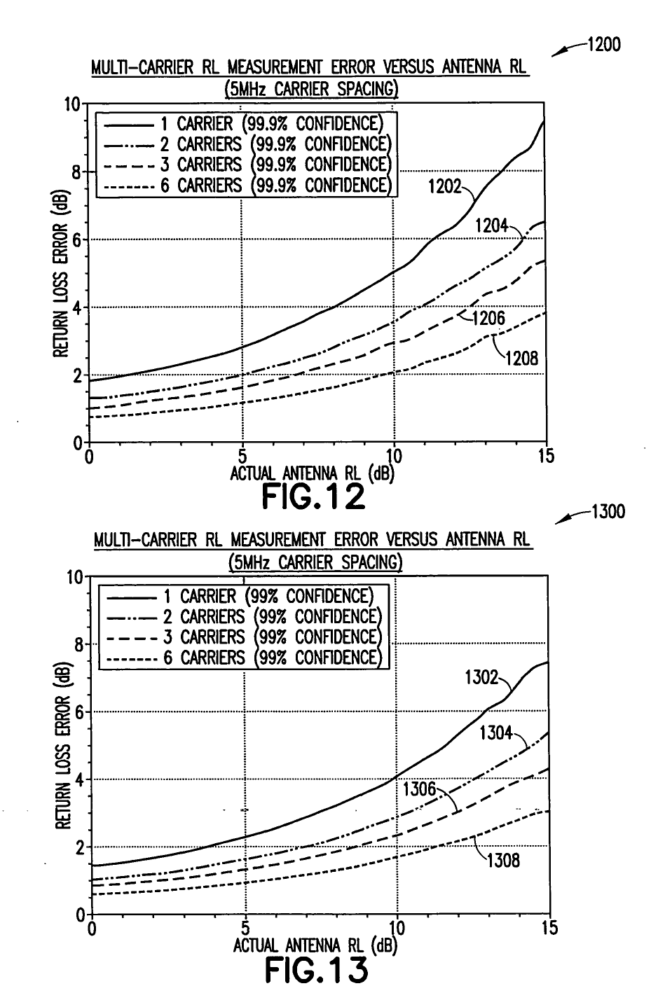

For the 900 band filter the total bandwidth is 35 MHz and uses roughly 8 poles to meet the response requirement. That means that the minimum carrier spacing to achieve reasonable phase decorrelation is about 5 MHz. The application of this observation to the previous result can be seen in FIGS. 12 and 13, which illustrate graphs 1200 and 1300, show ing multi-carrier measurement errors of 99.9% and 99% confidence, respectively, with the curves 1202 and 1302, 1204 and 1304, 1206 and 1306, and 1208 and 1308, showing the use of 1, 2, 3, and 6 carriers, respectively.

Embodiments of the present invention recognize that high return loss antenna loads are best achieved through the use of multiple wide spaced carriers. The use of fewer carriers will give results with lower confidence.

One or more embodiments of the invention address detection of antenna problems, and the more serious the problem that is being detected, the more important it is to prevent false alarms.

Standard deviation is a function of the antenna return loss, and solving exactly for the probability of a false detection is not straightforward. However, from the shape of the curve, a good approximation (0≦ANT_RL≦15 dB) is:

σ≈k₀+k₁·ANT_{—}RL² (5)

where k₀ and k₁ are constants for a given confidence level. Since 99.9% confidence is 2.46*sigma, the constants are determined to be k₀=0.8 and k₁=13.7e-3. Given the approximation to the standard deviation, it is straightforward to calculate the probability of raising an alarm as a function of ANT return loss for a given threshold setting:

$$\begin{matrix}{p}_{alarm} = \frac{1}{2} \cdot erfc ( \frac{ANT\_RL - ALARM\_RL}{σ} ) \\ = \frac{1}{2} \cdot erfc ( \frac{ANT\_RL - ALARM\_RL}{{k}_{0} + {k}_{1} \cdot {ANT\_RL}^{2}} )\end{matrix} \qquad ( 6 )$$

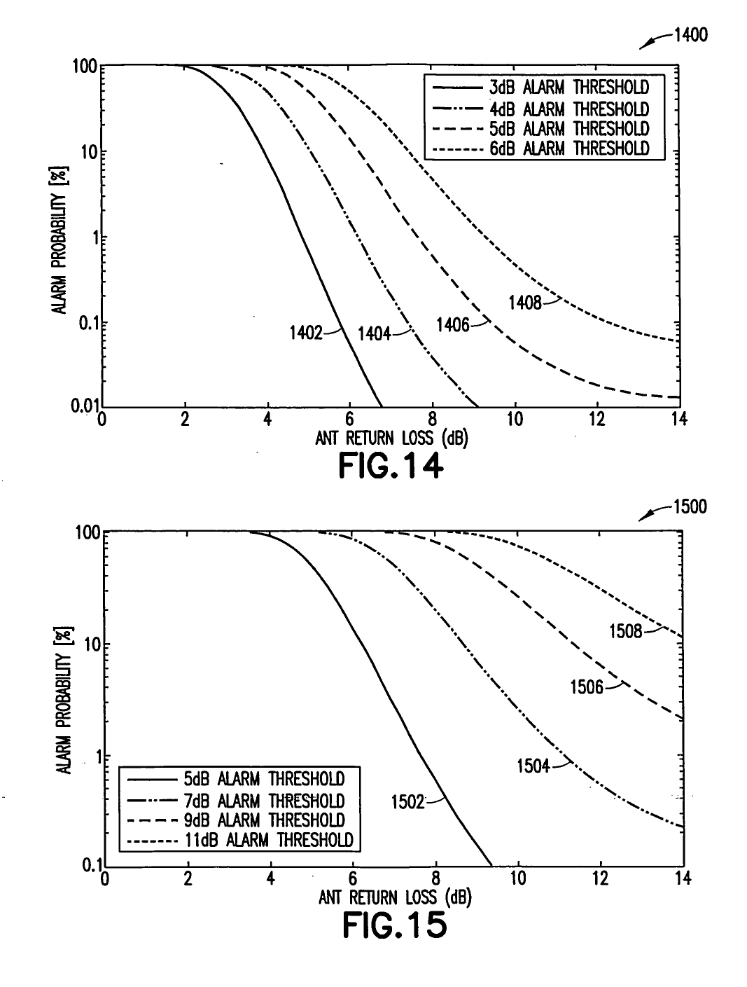

Since “Major Alarms” can result in transmitter shutdown, the confidence level of 99.9% might be appropriate, while 99% or lower would be acceptable for a “Minor Alarm.” FIGS. 14 and 15 illustrate false alarm probabilities for Major and Minor alarms, with FIG. 14 showing a graph 1400 presenting curves 1402, 1404, 1406, and 1408, for 3 dB, 4 dB, 5 dB, and 6 dB alarm thresholds, and FIG. 15 showing a graph 1500 presenting curves 1502, 1504, 1506, and 1508, for 5 dB, 7 dB, 9 dB, and 11 dB alarm thresholds.

It is best to use the lowest possible thresholds to minimize false alarms yet be able to detect serious antenna failures. For example, setting the Major Alarm threshold to 4 dB would almost cause an alarm on any antenna return loss less than 3 dB, but (with better than 99.9% confidence) would not alarm on any antenna return loss better than 8 dB. FIGS. 14 and 15 show that thresholds greater than 7 dB are of limited value due to false alarming probability in single carrier cases. But again, spreading the frequency out will reduce the errors and could make these higher thresholds somewhat useful.

In one or more embodiments of the invention, a VSWR measurement specification focuses on providing a rough estimate of the return loss at the ANT connector. It is “viewed” through the transmit filter, which presents a considerable source of error at a given frequency. Wideband signals, hopping, or both, serve to average out the error due to the filter and greatly improves the estimate. A simple calibration is needed to account for the gain difference between the forward power and reflected power measurement paths.

While various exemplary embodiments have been described above it should be appreciated that the practice of the invention is not limited to the exemplary embodiments shown and discussed here. Various modifications and adaptations to the foregoing exemplary embodiments of this invention may become apparent to those skilled in the relevant arts in vie of the foregoing description.

Further, some of the various features of the above non-limiting embodiments may be used to advantage without the corresponding use of other described features.

The foregoing description should therefore be considered as merely illustrative of the principles, teachings and exemplary embodiments of this invention, and not in limitation thereof.

1. A method comprising:
taking a forward power sample of a power amplifier of a transmitter by sampling a feedback signal used for power control of the amplifier, wherein the forward power sample is taken after attenuation;
sampling reflected power present at an output of the power amplifier, wherein the sampling is performed on a reflected power signal appearing at one or more of a circulator and an isolator, with sampling being performed after attenuation of the reflected power signal;
averaging samples to reduce measurement error, wherein averaging comprises averaging phase samples resulting from filter delays; and
estimating return loss of a load of the transmitter based on the sampling of the feedback signal and the reflected power.

2. The method of claim 1, wherein at least one of a circulator and an isolator is present at the output of the power amplifier and the reflected power is sampled at the at least one of the circulator and the isolator.

3. The method of claim 1, wherein the at least one of a circulator and an isolator is an isolator.

4. The method of claim 1, wherein the at least one of a circulator and an isolator is a circulator.

5. The method of claim 1, wherein the at least one of a circulator and an isolator is a combined circulator/isolator.

6. The method of claim 1, wherein forward power and reflected power are sampled along parallel analog paths and wherein estimating return loss is performed based at least in part on a difference between forward power and reflected power.

7. The method of claim 1, wherein modulation is removed from the forward power signal and the return power signal before sampling.

8. The method of claim 1, wherein a difference between samples of the forward and reflected power is determined by a differential amplifier.

9. The method of claim 1, wherein sampling the forward power and reflected power is followed by counting and accumulating samples at an application specific integrated circuit and passing an interrupt to a processor in response to the counting and accumulation being complete, so as to initiate processing of the samples.

10. The method of claim 1, further comprising generating a signal indicating if the return loss is at an acceptable level.

11. The method of claim 10, wherein the signal indicates that the return loss is at an unacceptable level in response to the exceeding of an alarm threshold by a deviation from the acceptable level.

12. The method of claim 11, wherein the alarm threshold is chosen based on a desired probability that an alarm indicates a failure.

13. An apparatus comprising:
a first detector configured to take a forward power sample of a power amplifier of a transmitter by sampling a feedback signal used for power control of the amplifier;
at least one of a circulator and an isolator at an output of the power amplifier;
a second detector configured to sample a reflected power observed at the circulator, with the sampling being accomplished after attenuation of the reflected power;
a comparison module configured to compare the forward power sample and the reflected power sample to produce a comparison signal providing a return loss estimate;
an analog to digital converter configured to digitize the comparison signal; and
a processing module for processing the digitized comparison signal to produce a return loss measurement based on the digitized comparison signal, with processing comprising post detection averaging to reduce measurement error, with averaging comprising averaging of phase samples resulting from filter delays.

14. The apparatus of claim 13, further comprising a comparator in the form of a differential amplifier, wherein the differential amplifier produces a comparator forward power level signal based on comparison of the forward power sample with a threshold, and wherein the processing module is configured to process the digitized comparison signal upon interpreting the comparator forward power level signal as an interrupt.

15. The apparatus of claim 14, wherein the differential amplifier produces the comparator forward power level signal based on a comparison of the forward power sample with a minimum power setpoint.

16. The apparatus of claim 13, further comprising first and second modulation removal filters configured to remove modulation from the first and second detectors, respectively.

17. The apparatus of claim 17, further comprising a comparator receiving as inputs a minimum power setpoint value and at least one modulation-free signal from at least one of the modulation removal filters, and produce, based on the inputs, an output signal indicating whether or not the signal levels are sufficient to make a valid measurement.

18. The apparatus of claim 13, wherein the processing module signals a transmitter fault based on a comparison with the return loss against a threshold.

19. The apparatus of claim 13, wherein the threshold is chosen based on a probability that a return loss exceeding the threshold indicates a transmitter fault.

20. The apparatus of claim 13, wherein forward power and reflected power are sampled along parallel analog paths and wherein estimating return loss is based at least in part on a difference between forward power and reflected power.
